(19) United States
(12) Patent Application Publication
(10) Pub. No.: US 2013/0130434 A1
(43) Pub. Date: May 23, 2013

(54) Method for Producing a Photovoltaic Element Comprising a Silicon Dioxide Layer

(71) Applicant: OSRAM AG, Munich (DE)

(72) Inventors: Markus ROTH, Bonn (DE); Siegmar Rudakowski, Ratingen (DE)

(73) Assignee: OSRAM AG, Munich (DE)

(21) Appl. No.: 13/654,088

(22) Filed: Oct. 17, 2012

(30) Foreign Application Priority Data
Oct. 17, 2011 (DE) 10 2011 084 644.1

(51) Int. Cl. H01L 31/18

(52) U.S. Cl. CPC H01L 31/18
USPC 438/98

(57) ABSTRACT

Production of a photovoltaic element, more particularly of a solar cell. In this case, an additional silicon dioxide layer is used, which is produced by UV irradiation with a wavelength of less than 200 nm and can improve the interface properties on the silicon and can help to reduce disturbances known by the expression “background plating”.

### RELATED APPLICATIONS

This application claims the priority of German application no. 10 2011 084 644.1 filed Oct. 17, 2011, the entire content of which is hereby incorporated by reference.

### FIELD OF THE INVENTION

The invention relates to a method for producing photovoltaic elements.

### BACKGROUND OF THE INVENTION

The production of photovoltaic elements, more particularly of so-called solar cells, on the basis of silicon substrates has been known for decades and is the subject of extensive development activity.

In the known production methods, silicon nitride layers are generally used on the substrate, said layers having tasks appertaining to increasing the charge carrier lifetime and suppressing reflections. Such layers can be deposited e.g. by means of plasma methods, in particular PECVD methods (plasma enhanced chemical vapor deposition).

Openings are introduced into the silicon nitride layer in order to make contact with conductive regions in the silicon substrate, e.g. p-doped layers therein, and to connect them to conductor tracks.

### SUMMARY OF THE INVENTION

One object of the invention is to provide a further improvement for these production methods.

One aspect of the present invention is directed to a method for producing a photovoltaic element comprising the following steps:
producing a silicon nitride layer on a silicon substrate,
producing openings in the silicon nitride layer,
producing a conductive contact-connection situated at least
partly in the opening of the silicon nitride layer, characterized in that before the contact-connection is produced, a silicon dioxide layer is produced on the silicon substrate, and the silicon dioxide layer is produced by oxidation of silicon during irradiation with UV light having a wavelength of less than 200 nm in the presence of at least one from the group of O species and O-H species.

In addition, an embodiment of the invention also relates to a corresponding use of a UV source.

An embodiment of the invention includes a silicon dioxide layer which is produced by a UV-driven process involving O species and/or O-H species and corresponding oxidation of silicon to form silicon dioxide. In this case, the term “0 species” is intended to encompass the different modifications of pure oxygen, that is to say atomic O or customary molecular O₂ but also radicals derived therefrom, and ozone. Accordingly, the term “O-H species” is intended to encompass a wide variety of molecular species composed of hydrogen and oxygen atoms, that is to say, in particular, normal water (H₂O); hydrogen peroxide (H₂O₂) corresponding ions and radicals, e.g. hydroxyl radicals. An embodiment of the invention is based on the fact that UV quanta having a wavelength of less than 200 nm can generate efficiently and easily from said O species or O-H species an atmosphere which oxidizes silicon at moderate temperature comparatively rapidly and with high quality. By way of example, the UV quanta can dissociate molecular oxygen and in the process create not only ozone but also atomic oxygen radicals which directly oxidize silicon.

The layer according to the invention provides for improved electrical insulation in addition to the nitride layer. In particular, the oxide layer can afford additional insulation for defects and holes in the nitride layer that are practically unavoidable in production-governed and many cases. In particular, it is thus possible to reduce or avoid disturbances which are known by the term “background plating” and which, during subsequent electrolytic metallization processes, provide for metal deposition to arise undesirably in and in the vicinity of such defects. Specifically, if porosities or holes unintentionally leave the substrate free, then the latter is oxidized during the metal deposition and thus electrically insulated. Accordingly, this location that is otherwise predestined for island growth is “passivated” during the subsequent electrodeposition or electrolytic processes. Alternately, these improvements are beneficial for reducing rejects and improving the efficiency of the photovoltaic elements.

The production according to the invention by means of a UV-driven oxidation avoids high thermal loads in the production method and can be used on an industrial scale without significant difficulties and with comparatively less energy expenditure (relative to traditional thermal oxide).

Preferably, the silicon dioxide layer is produced temporally before the nitride layer is produced. Although it could also be produced thereafter, but before the contact-connection or metallization, the earlier incorporation of the oxidation layer step is more expedient: experience shows that the interface between the silicon dioxide produced according to the invention and the adjoining regions of the silicon substrate is of better quality, particularly with regard to density of recombination centers, and the interface between the silicon substrate and defective nitride layers. Accordingly, it is particularly preferred to carry out the oxidation over a large area and continuously at least in the regions in which the nitride layer remains during the contact-connection (and, in particular, is not removed for the contact-connection openings mentioned. Furthermore, preferably exclusively molecular oxygen (O₂) is used as a starting basis for the oxidation step, that is to say as a source. Owing to the UV irradiation, it does not remain, of course, rather the result is the dissociation of the molecules and production of ions and free radicals, possibly the production of a plasma as well. The statement of the exclusive use of molecular oxygen therefore refers to the supply from a source and not to the composition of the actually active atmosphere.

A particularly efficient and advantageous choice for a UV source is excimer discharge lamps. In such lamps known per se, a so-called silent discharge is ignited and operated, in which at least a portion of the electrodes is separate from the discharge medium by a dielectric layer. The production of unstable excimers, in particular of noble gas molecules, can occur in the discharge. One example which is known per se and preferred here is Xe₂* excimer lamps. In this case, the term “lamp” is intended to encompass a UV source of, in principle, any geometrical extent. This therefore involves a UV source in the general sense. The excimer lamps described are particularly well suited to dimensionings that are very large in one or more than one dimension, such as are desired in industrial production processes particularly for solar cells.

The silicon nitride layer is preferably deposited by means of a PECVD method known per se. These methods lead to a layer quality which, apart from the described problem of “background plating”, is otherwise totally suitable, and meet the optical requirements, in particular. They can be realized on an industrial scale at low costs and in a controlled fashion.

The contact-connection provided in the abovementioned openings of the nitride layer can be embodied, in particular, uniformly with a conductor track system. Preferably, the corresponding technology is metallic, but free of silver, because the previously known systems containing silver lead to high costs.

Primarily electrodeposited copper layers are appropriate, such as can be produced e.g. after seeding for instance with chemically deposited chromium or nickel. In this case, a correspondingly thin chemical metal layer between the silicon substrate and the electrodeposited copper can also serve as a diffusion barrier for preventing copper from diffusing into the substrate or conductive layer thereon.

The combating of the problem “background plating” according to the invention makes the use of electrodeposited conductor tracks very much more attractive; owing to “background plating”, the prior art has also resorted to comparatively more expensive printing processes using silver pastes which, in a so-called co-firing process, chemically break through a silicon nitride layer and can thus produce a contact-connection.

The openings in the nitride layer which have already been mentioned a number of times can be produced e.g. by laser bombardment; in this case, the nitride layer chips off or vaporizes and exposes the substrate. Advantageously, the silicon dioxide layer also vaporizes on this occasion, such that the laser bombardment exposes the silicon substrate itself. Previous structuring of the silicon dioxide is thus obviated.

A range of between 0.5 nm and 10 nm has proved to be a suitable thickness for the oxide layer. Thicker layers are not required, but are not necessarily disturbing. Preferred lower limits are 1 nm, 1.5 nm and 2 nm; more preferred upper limits are 8 nm, 6 nm and finally 4 nm.

Particularly in connection with the excimer UV sources mentioned, the process according to the invention can be incorporated into industrial manufacture in the context of an inline method. Specifically, this process is integrated without additional waiting times in a method sequence. Preferably, solar cell substrates, individually or as a plurality, are led past a UV source (or vice versa), this being temporally coordinated with other method steps.

### BRIEF DESCRIPTION OF THE DRAWINGS

The invention will be explained in greater detail below on the basis of an exemplary embodiment.

FIG. 1 shows a perspective schematic illustration of production according to an embodiment of the invention of a silicon dioxide layer on solar cell substrates.

FIGS. 2A-2H show schematically and step-by-step an overview of a process according to an embodiment of the invention.

### PREFERRED EMBODIMENT OF THE INVENTION

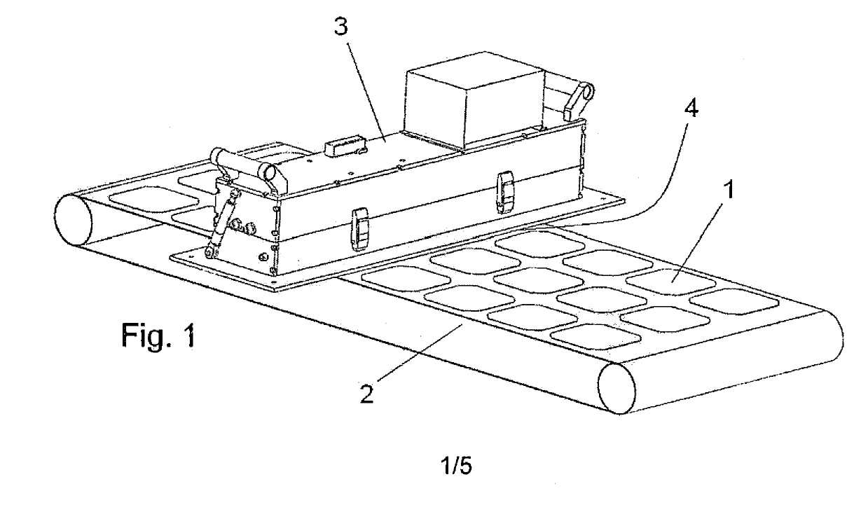

FIG. 1 schematically shows a conveyor belt 2, on which individual solar cell substrates 1 are transported, as indicated by the arrow with the symbol v for the velocity of the belt. Said conveyor belt 2 is representative of an inline process in which the production of the silicon dioxide layer signifies only one process step among many.

Situated above the conveyor belt 2 is a luminaire 3 comprising an Xe excimer UV lamp in tubular form mounted therein. For the more detailed embodiment of said luminaire, reference is supplementarily made to WO 2010/066298 A1, in FIG. 1 of which the tubular UV lamp is designated by 1 and is mounted together with specific reflectors 2 in a housing—similar to the present housing of the luminaire 3—having the reference sign 4-8. The UV lamp is a commercial type having the trade designation Xeradex, which generates substantially UV light having the wavelength of 172 nm. The cited document discusses this and the construction of the luminaire in more specific detail.

The housing of the luminaire 3 is hermetically sealed for safety reasons; FIG. 1 reveals corresponding closures at that side of said housing which faces toward the front on the right. Situated below the flat underside of said housing is a narrow interspace 4 filled with air or, in order to reduce the UV absorption, with an oxygen-reduced atmosphere (e.g. artificial air comprising 1% O₂ and 99% N₂). As a result, the distance between the substrates 1 and the luminaire 3 does not have to be complied with so exactly. On the silicon substrates 1, the silicon surface is oxidized very efficiently by the hard UV irradiation.

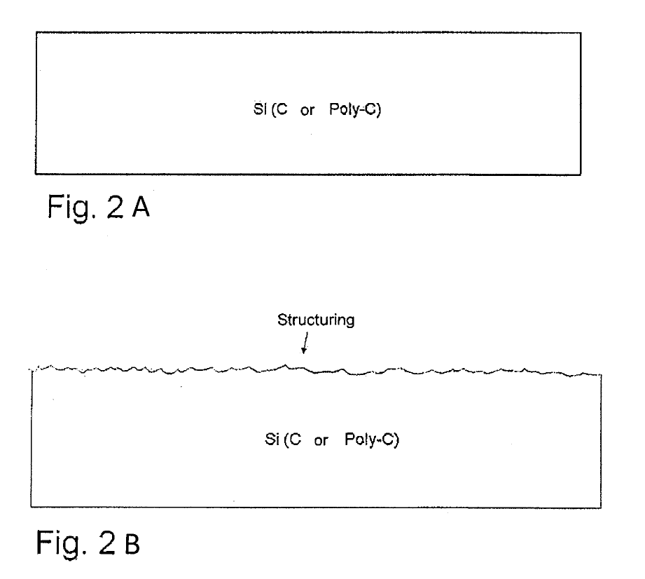

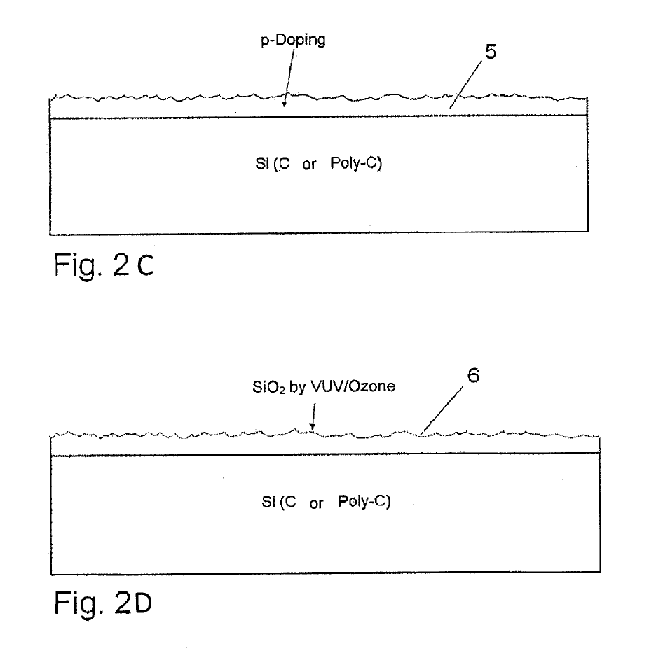

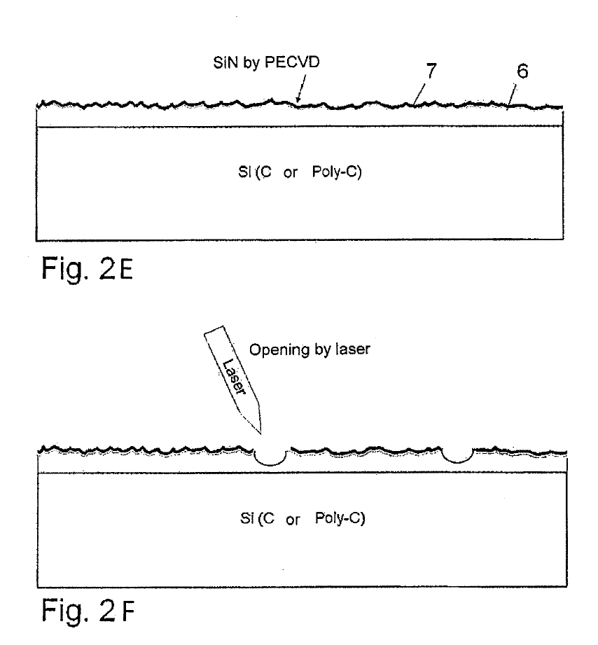

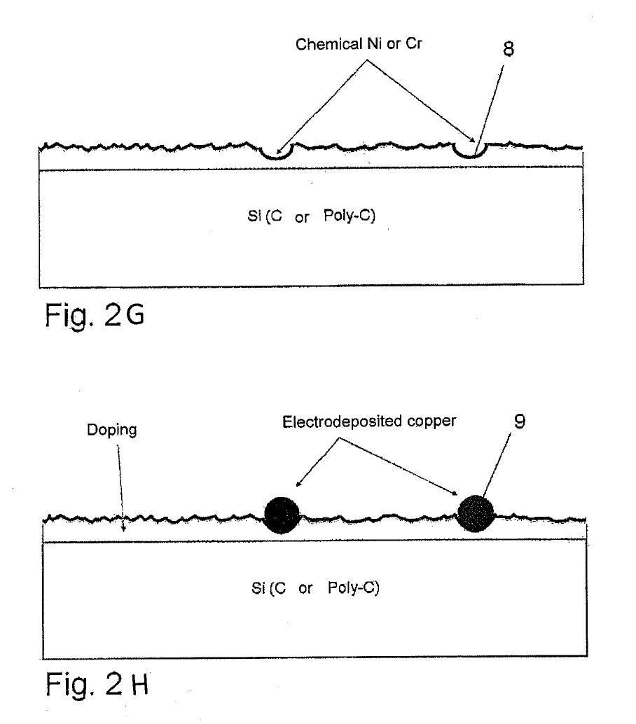

FIGS. 2A-2H show an overview in a sequence of individual illustrations: firstly, FIG. 2A reveals a merely cleaned silicon substrate, which can be crystalline or polycrystalline. Said substrate is structured in a manner known per se, cf. FIG. 2B, and p-doped, cf. FIG. 2C. In the step in accordance with FIG. 2D, the thin silicon dioxide layer 6 according to the invention is produced on the p-doped ply 5 produced in step 2C, to be precise in accordance with FIG. 1. A silicon nitride layer 7 is deposited thereon by PECVD in accordance with FIG. 2E, and is opened in places by laser bombardment in accordance with FIG. 2F. The silicon oxide layer 6 and part of the p-doped layer are also removed in the process. A chemical nickel layer or chromium layer 8 is deposited into these openings in accordance with FIG. 2G, and is reinforced with electrodeposited copper 9 in accordance with FIG. 2H.

The scope of protection of the invention is not limited to the examples given hereinabove. The invention is embodied in each novel characteristic and each combination of characteristics, which includes every combination of any features which are stated in the claims, even if this feature or combination of features is not explicitly stated in the examples.

1. A method for producing a photovoltaic element comprising the following steps:
producing a silicon nitride layer on a silicon substrate;
producing openings in the silicon nitride layer;
producing a conductive contact-connection situated at least partly in the opening of the silicon nitride layer;
before the contact-connection is produced, a silicon dioxide layer is produced on the silicon substrate; and
the silicon dioxide layer is produced by oxidation of silicon during irradiation with UV light having a wavelength of less than 200 nm in the presence of at least one from the group of O species and O-H species.

2. The method as claimed in claim 1, wherein the silicon dioxide layer is produced temporally before the silicon nitride layer and spatially between the latter and the silicon substrate.

3. The method as claimed in claim 2, wherein the silicon dioxide layer is produced over the whole area at least where the silicon nitride layer still exists when producing the contact-connection.

4. The method as claimed in claim 1, wherein the silicon dioxide layer is produced using O₂ atmosphere and without addition of further gases, wherein further O species arise from the O₂ as a result of the UV light.

5. The method as claimed in claim 1, wherein the UV light is generated by means of an excimer UV source.

6. The method as claimed in claim 5, wherein the excimer UV source is an Xe₂* lamp.

7. The method as claimed in claim 1, wherein the silicon nitride layer is deposited by means of a PECVD method.

8. The method as claimed in claim 1, wherein the contact-connection is a silver-free metallization.

9. The method as claimed in claim 8, wherein the metallization comprises electrodeposited copper.

10. The method as claimed in claim 1, wherein the openings in the silicon nitride layer are produced by laser bombardment.

11. The method as claimed in claim 1, wherein the silicon dioxide layer produced has a thickness of between 0.5 nm and 10 nm.

12. The method as claimed in claim 1, which is configured as an inline method.

13. The use of a UV source having a wavelength of less than 200 nm during the production of a photovoltaic element for producing a silicon dioxide layer between a silicon substrate and a silicon nitride layer thereon.
